(19) United States
(12) Patent Application Publication
(10) Pub. No.: US 2025/0102238 A1
(43) Pub. Date: Mar. 27, 2025

(54) UNIVERSAL RETENTION FOR COOLING DEVICES, AND ASSOCIATED SYSTEMS AND METHODS

(71) Applicant: CoolIT Systems, Inc., Calgary (CA)

(72) Inventors: Lucas Loyst, Calgary (CA); Seyed Kamaleddin Mostafavi Yazdi, Calgary (CA)

(21) Appl. No.: 18/891,934

(22) Filed: Sep. 20, 2024

Related U.S. Application Data
(60) Provisional application No. 63/584,863, filed on Sep. 22, 2023.

(51) Int. Cl. F28D 21/00

(52) U.S. Cl. CPC F28D 21/00; F28D 2021/0028; F28F 2280/06

(57) ABSTRACT

A retainer includes a bracket configured to engage with a heat transfer unit. The bracket defines a plurality of retention holes. The retainer further includes a movable selector comprising one or more indexable features that selectively align with a first one or more of the plurality of retention holes defined by the bracket when the movable selector is in a first position and with a second one or more of the plurality of retention holes defined by the bracket when the movable selector is in a second position.

### CROSS-REFERENCE TO RELATED APPLICATION(S)

This application claims priority to and benefit of U.S. Provisional Patent Application No. 63/584,863, filed on Sep. 22, 2023, and entitled “UNIVERSAL RETENTION FOR COOLING DEVICES, AND ASSOCIATED SYSTEMS AND METHODS,” the contents of which are hereby incorporated by reference in their entirety as if recited in full herein, for all purposes.

### FIELD

This application and the subject matter disclosed herein (collectively referred to as the “disclosure”), generally concern components, devices, and systems for facilitating heat transfer, and related methods. More particularly, but not exclusively, this disclosure pertains to one or more components of a mechanical retention system for retaining a heat transfer unit (e.g., including a heat sink) adjacent to a surface of a heat source (e.g., a processing unit or other electrical component/device).

### BACKGROUND INFORMATION

This application pertains to concepts disclosed in U.S. Pat. No. 9,534,852, issued Jan. 3, 2017, which enjoys benefit of priority to U.S. Patent Application No. 61/726,386, filed Nov. 14, 2012, the contents of both of which are hereby incorporated by reference in their entirety as if recited in full herein, for all purposes.

Many industrial processes, consumer goods, power generators, combustion chambers, communication devices, electronic components, electrical storage components (e.g., batteries), etc., and associated systems, rely on heat transfer to function as intended. For example, some rely on cooling (e.g., radio transmitters) and others rely on heating (e.g., endo-thermic chemical reactions) to maintain a temperature within a specified range between an upper threshold temperature and a lower threshold temperature.

The prior art has responded to these challenges with a number of techniques for transferring heat from one medium to another. For example, conventional air cooling uses a fan or other air-mover to draw heat away from or to convey heat to another medium. Air cooling can be supplemented with an air-cooled heat sink, e.g., often a plate of thermally conductive material having surfaces, or fins, extending from the plate to provide a larger surface area available for transferring heat to or from the air flowing over the extended surfaces.

Some heat-transfer systems use a liquid to transfer heat, as many liquids provide a relatively higher rate of convective heat transfer compared to gasses, e.g., air. In still other systems, a heat-transfer fluid can change phase from liquid to gas (or vice-versa) to absorb (or to dissipate, respectively) relatively large amounts of energy over a narrow range of temperatures. Some prior phase-change systems include a pump to increase an operating pressure of the heat-transfer fluid to urge the heat-transfer fluid through a given circulation loop, as well as to manipulate the thermodynamic state of the heat-transfer fluid to achieve a desired heat-transfer performance from the fluid. Such liquid or phase-change cooling can be accommodated by passing a coolant (e.g., as a liquid phase, or as a saturated mixture of liquid phase and gas phase) over fins extending from a surface heated by a heat source. As used herein, the term “heat transfer unit” refers to any heat transfer device, e.g., a heat sink or a cold plate, that absorbs heat through a heat-transfer surface and conveys the heat to a coolant, regardless of whether the coolant is in a gas phase, a liquid phase, or a saturation phase. A heat transfer unit (e.g., a heat sink or cold plate) can include a heat transfer surface or material and various componentry thereof or attached thereto (e.g., fluid ports and/or conduits, brackets, housings, connection/latching features, etc.). Example heat transfer units can include active cooling units ((e.g., cold plates, heat sinks, all-in-one coolers, etc.) that including moving parts and/or powered components that urge a heat-transfer fluid (in liquid or gas phase) therethrough to transfer heat to or from the fluid) or passive cooling units (e.g., cold plates, heat sinks, all-in-one coolers, etc., that omit moving parts and/or powered components that urge a heat-transfer fluid therethrough, despite that such moving parts and/or powered components may be included elsewhere in the heat-transfer system that incorporates the passive cooling unit).

### SUMMARY

Some commercially available heat transfer units can be used to cool a variety of different electronic components with different form factors. However, the variety of different electronic components may be incorporated in a variety of electronic systems and devices, each with a distinct or different mounting location (and, likely, a unique mount) available to retain a heat transfer unit suitable to cool the electronic component. For example, some systems and devices provide mounting holes through a circuit board in specified locations relative to the electronic component that needs to be cooled by the heat transfer unit. Other systems and devices provide different mounting holes through a different circuit board in different specified locations relative to the electronic component that needs to be cooled by the heat transfer unit. And still other systems provide threaded studs, perhaps in still other locations relative to the electronic component. Accordingly, more than one, and often many, retention elements typically accompany each heat transfer unit to allow the eventual user to select a retention element that corresponds to the specific mounting arrangement provided by the user's system or device.

By embodying disclosed principles, a single retainer (or set of retainers) as disclosed herein can be substituted for plural retention elements that conventionally have accompanied heat transfer units intended for use across a variety of different electronic components in a variety of different systems and/or devices. Disclosed retainers can simplify assembly for users, as they no longer need to determine the correct bracket(s) from multiple sets of brackets. Moreover, since disclosed retainers can be smaller and lighter, and can eliminate the need for plural retention elements, overall packaging weight for heat transfer units can be reduced compared to packaging for heat transfer units that include several different sets of retention elements. Moreover, lighter packaging and fewer parts can facilitate a reduction in waste, including wasted materials and wasted manufacturing effort since, in many cases involving conventional retention elements packaged together, the end user discards all but one conventional retention element (or set thereof) to retain a heat transfer unit. Further, due to the reduction in material usage and lower bulk packaging weight, emissions attributable to the heat transfer unit and its retention can be reduced by implementing the disclosed principles.

According to a first aspect, a retainer includes a bracket configured to engage with a heat transfer unit. The bracket defines a plurality of retention holes. The retainer further includes a movable selector comprising one or more indexable features that selectively align with a first one or more of the plurality of retention holes defined by the bracket when the movable selector is in a first position and with a second one or more of the plurality of retention holes defined by the bracket when the movable selector is in a second position.

In some embodiments, the movable selector selectively obscures the second one or more of the plurality of retention holes defined by the bracket when the movable selector is in the first position. The movable selector can selectively obscure the first one or more of the plurality of retention holes defined by the bracket when the movable selector is in the second position.

In some embodiments, the one or more indexable features comprise one or more modular mounting holes.

In some embodiments, the movable selector comprises a rotatable disc that is selectively rotatable from the first position to the second position and from the second position to the first position.

In some embodiments, the retainer further includes a housing that at least partially covers the bracket and the movable selector. The housing can movably secure the movable selector to the bracket. The movable selector can include (i) a first location indicator associated with the first position and (ii) a second location indicator associated with the second position. The housing can include a viewing window. The first location indicator of the movable selector can align with the viewing window when the movable selector is in the first position, and the second location indicator of the movable selector can align with the viewing window when the movable selector is in the second position.

In some embodiments, the housing or the bracket comprise a latching feature configured to engage with a corresponding latching feature of the heat transfer unit. The housing can form a slot configured to receive the corresponding latching feature of the heat transfer unit. The latching feature of the housing or the bracket can be positioned within the slot.

In some embodiments, the bracket further comprises a second plurality of retention holes. The retainer can further include a second movable selector comprising one or more second indexable features that selectively align with a first one or more of the second plurality of retention holes defined by the bracket when the second movable selector is in a corresponding first position and with a second one or more of the second plurality of retention holes defined by the bracket when the second movable selector is in a corresponding second position. The housing can at least partially cover the second movable selector and movably secures the second movable selector to the bracket. The retainer can further include a coupling element that couples the movable selector to the second movable selector such that: (i) movement of the movable selector to the first position causes movement of the second movable selector to the corresponding first position, (ii) movement of the movable selector to the second position causes movement of the second movable selector to the corresponding second position, (iii) movement of the second movable selector to the corresponding first position causes movement of the movable selector to the first position, and (iv) movement of the second movable selector to the corresponding second position causes movement of the movable selector to the second position. The coupling element can comprise one or more gears engaged with gear teeth of the movable selector and the second movable selector. The housing can at least partially cover the coupling element or movably secure the coupling element to the bracket.

According to another aspect, a heat transfer system includes a heat transfer unit and a retainer. The retainer includes a latching feature configured to engage with a corresponding latching feature of the heat transfer unit and a bracket defining a plurality of retention holes. The retainer further includes a movable selector comprising one or more indexable features that selectively align with a first one or more of the plurality of retention holes defined by the bracket when the movable selector is in a first position and with a second one or more of the plurality of retention holes defined by the bracket when the movable selector is in a second position.

In some embodiments, the retainer further includes a housing that at least partially covers the movable selector and that movably secures the movable selector to the bracket. The housing can form a slot configured to receive the corresponding latching feature of the heat transfer unit. The latching feature of the retainer can be positioned within the slot.

In some embodiments, the one or more indexable features of the movable selector selectively align with a third one or more of the plurality of retention holes defined by the bracket when the movable selector is in a third position.

In some embodiments, the heat transfer system further includes a second retainer. The second retainer can include a second latching feature configured to engage with a second corresponding latching feature of the heat transfer unit and a second bracket defining a second plurality of retention holes. The second retainer can further include a second movable selector comprising one or more second indexable features that selectively align with a first one or more of the second plurality of retention holes defined by the second bracket when the second movable selector is in a corresponding first position and with a second one or more of the second plurality of retention holes defined by the second bracket when the second movable selector is in a corresponding second position.

According to yet another aspect, an electronic device includes a substrate, a heat transfer unit, and an electronic component mounted to the substrate. The substrate can include one or more mounting elements configured to allow a user to mount the heat transfer unit to the substrate while maintaining thermal contact between the heat transfer unit and the electronic component. Each of the one or more mounting elements can be positioned relative to a mounted position of the electronic component. The electronic device can further include a retainer having a bracket defining a plurality of retention holes and a movable selector having one or more indexable features that selectively align with a first one or more of the plurality of retention holes defined by the bracket when the movable selector is in a first position and with a second one or more of the plurality of retention holes defined by the bracket when the movable selector is in a second position. Selected ones of the plurality of retention holes defined by the bracket and selected ones of the one or more indexable features of the movable selector can align with each of the one or more mounting elements defined by the substrate when the movable selector is in a selected position.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIGS. 1 and 2 illustrate isometric views of mounting brackets for heat transfer systems.

FIG. 3 illustrates an isometric view of a bracket of a modular retainer for a heat transfer system.

FIGS. 4A, 4B, and 4C illustrate isometric views of a bracket as in FIG. 3 combined with movable selectors of a modular retainer.

FIG. 5 illustrates an isometric view of a bracket and movable selectors as in FIGS. 4A, 4B and 4C, together with a coupling element of a modular retainer for a heat transfer system.

FIG. 6 illustrates an exploded view of a modular retainer incorporating a bracket, movable selectors and a coupling element as in FIG. 5.

FIG. 7 illustrates an isometric view of a modular retainer as in FIG. 6.

FIG. 8 illustrates a front perspective view of a modular retainer as in FIGS. 6 and 7.

FIG. 9A illustrates an isometric view of a heat transfer system including modular retainers positioned near a heat transfer unit.

FIG. 9B illustrates an isometric view of the heat transfer system shown in FIG. 9A with the modular retainers engaged with the heat transfer unit.

FIG. 10A illustrates an isometric view of a heat transfer system positioned to mount over an electronic component mounted to a substrate.

FIG. 10B illustrates an isometric view of the heat transfer system shown in FIG. 10A with the heat transfer system mounted to the substrate and in thermal contact with the electronic component.

FIGS. 11 and 12 illustrate isometric views of alternative embodiments of a bracket and movable selectors suitable for modular retainers.

### DETAILED DESCRIPTION

The following describes various principles pertaining to mechanical retention systems, and related components and/or methods. That said, descriptions herein of specific apparatus configurations and combinations of method acts are but particular examples of the variety of contemplated embodiments, chosen as being convenient to illustrate disclosed principles. One or more of the disclosed principles can be incorporated in various other embodiments to achieve any of a variety of corresponding system characteristics.

Thus, embodiments of disclosed principles having attributes that are different from those specific embodiments discussed herein can embody one or more presently disclosed principles, and can be used in applications not described herein in detail. Accordingly, such alternative embodiments also fall within the scope of this disclosure.

### I. Overview

As noted above, conventional retainers for heat transfer units can be used to cool a variety of different electronic components produced by different manufacturers. Heat transfer units are used to cool a variety of electronic components, such as, by way of non-limiting example, central processing units, graphics processing units, neural processing units, holographic processing units, power supply units/components, memory (e.g., random access memory, solid state or hard disk drives, etc.), chipsets, network interface components, sound components, and/or others.

Electronic components to be cooled by heat transfer units are often mounted on a substrate, such as, for example, a motherboard or primary circuit board, a printed or flexible circuit board, a daughterboard, a rigid-flex circuit, a backplane, a module board, a memory module, an expansion card, an interposer, etc. Substrates that support electronic components often include mounting elements to which heat transfer systems can be mounted, thereby achieving retention of the heat transfer systems in thermal communication with the electronic components. However, such mounting elements for mounting a heat transfer system can be provided in different locations on the substrates relative to the electronic component. For instance, a substrate for a first type of electronic component (e.g., a first class, design, brand, or form factor of electronic component) can include heat transfer unit mounting elements with a first positional configuration relative to the electronic component, whereas a substrate for a second type of electronic component can include heat transfer unit mounting elements with a second, different positional configuration relative to the electronic component.

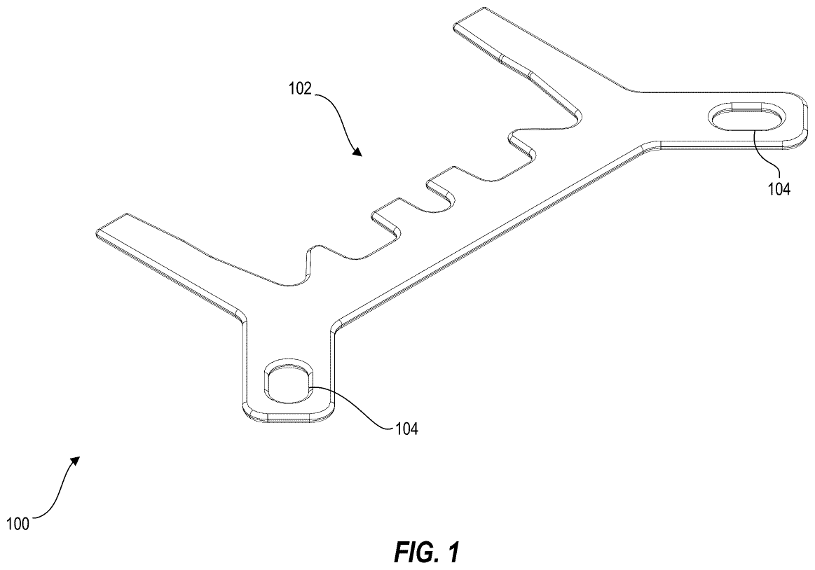

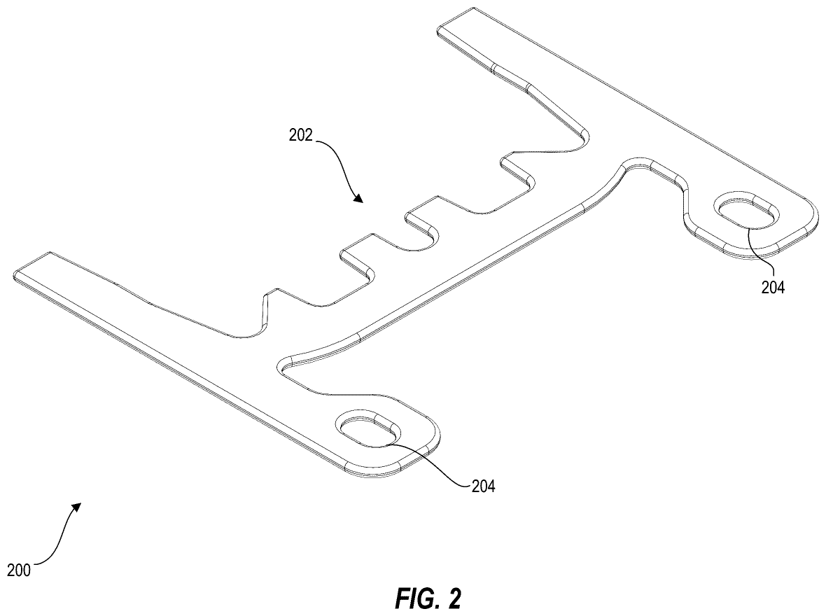

In view of the foregoing, manufacturers/providers of heat transfer units often provide multiple sets of mounting brackets with a single heat transfer unit. Each set of mounting brackets included with a heat transfer unit can conform to a different positional configuration of mounting elements for substrates supporting electronic components, enabling the heat transfer unit to be mounted to substrates supporting multiple types of electronic components. FIGS. 1 and 2 illustrate isometric views of mounting brackets 100 and 200, respectively, for a heat transfer unit. The mounting brackets 100 and 200 each include a heat transfer unit interface 102 and 202, respectively, which enable the mounting brackets 100 and 200 to connect to the same heat transfer unit. For instance, a set of two mounting brackets 100 and a set of two mounting brackets 200 may be packaged with a single heat transfer unit, enabling users to select either the mounting brackets 100 or the mounting brackets 200 to connect to the heat transfer unit to facilitate mounting of the heat transfer unit to substrate supporting an electronic component.

As shown in FIGS. 1 and 2, the mounting brackets 100 and 200 each include retention holes 104 and 204, respectively, which can be configured to align with mounting elements of substrates for mounting a heat transfer unit to the substrates. Because the heat transfer unit interfaces 102 and 202 of the different mounting brackets 100 and 200 are configured to connect to the same heat transfer unit, FIGS. 1 and 2 show that the retention holes 104 and 204 of the different mounting brackets 100 and 200 have different relative positioning, enabling mounting bracket 100 to facilitate mounting of a heat transfer unit to a first configuration of mounting elements (e.g., for a first type of electronic component) and enabling mounting bracket 200 to facilitate mounting of a heat transfer unit to a second, different configuration of mounting elements.

The inclusion of multiple sets of retainers with a single heat transfer system can result in customer confusion, installation difficulty, increased packaging weight/bulk, manufacturing waste, increased emissions, and/or other shortcomings.

At least some modular retainers (or simply “retainers”) can be selectively configured by end users to accommodate different mounting element configurations for mounting heat transfer units on substrates. Such modular retainers can be provided in conjunction with heat transfer units to provide a heat transfer systems usable in conjunction with different types of substrates or electronic components/devices.

A modular retainer may comprise a bracket with one or more sets of retention holes. Each set of retention holes can be associated with a unique substrate configuration (or relative positioning of mounting elements), enabling the bracket to align with mounting elements according to multiple different positional configurations. The modular retainer may also comprise one or more movable selectors with indexable features that can be selectively aligned with the different sets of retention holes of the bracket. For instance, the movable selector(s) may be implemented as one or more rotatable discs, and the indexable features may be implemented as modular mounting holes on the disc(s), enabling the disc(s) to be rotated into alignment with the different sets of retention holes of the bracket. The disc(s) may be configured to only reveal one set of retention holes at a time, which can mitigate end user confusion at installation.

In some instances, the disc(s) can include location indicators (e.g., text on the disc(s)) associated with each set of retention holes, which can readily communicate to end users the mounting element configuration with which the disc(s) is currently aligned. For example, the disc(s) and the bracket may be at least partially enclosed by a housing, and the housing may include a viewing window configured to reveal only one location indicator at a time, enabling users to readily determine which mounting element configuration the disc(s) is currently aligned with.

In some instances, a modular retainer includes multiple rotatable discs (or other movable selectors) arranged over respective pluralities of retention holes. A modular retainer may include a coupling element, such as a gear train, that couples the rotatable discs together to transfer motion such that both discs rotate simultaneously (e.g., in opposite directions). Such features can enable users to easily configure a modular retainer for a particular substrate mounting element configuration. For instance, the coupling element can allow users to manipulate a single disc(s) to cause alignment of multiple disc(s) with a selected set of retention holes of the bracket.

### II. Modular Retainers and Components Thereof

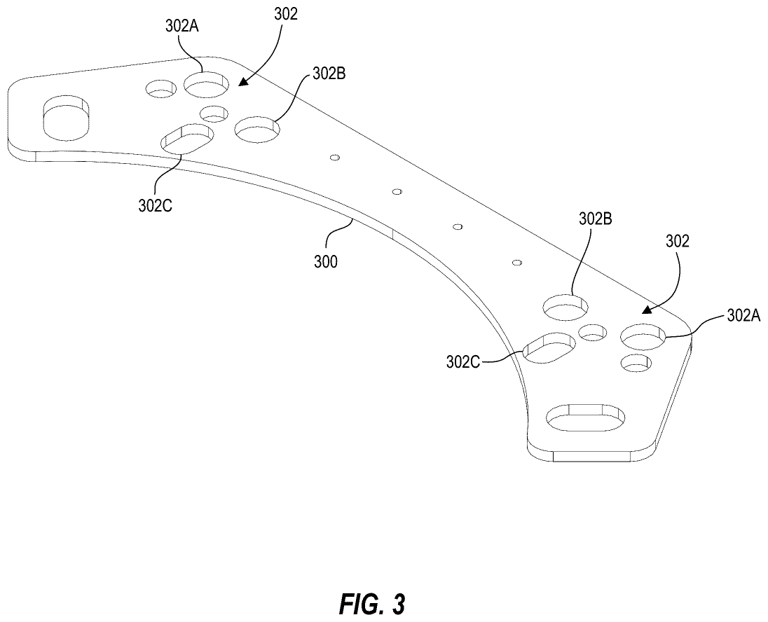

FIG. 3 illustrates an isometric view of a bracket 300 of a modular retainer. The bracket 300 includes retention holes 302 forming multiple sets of retention holes. In the example shown in FIG. 3, the retention holes 302 of the bracket 300 include a first set of retention holes 302A, a second set of retention holes 302B, and a third set of retention holes 302C. Each of the different sets of retention holes 302A, 302B, and 302C of the bracket 300 is associated with a respective mounting element configuration. For instance, the first set of retention holes 302A can be arranged to align with mounting elements of a substrate (e.g., motherboard) with a first electronic component socket or mounting element configuration (e.g., TR4(L)), the second set of retention holes 302B can be arranged to align with mounting elements of a substrate with a second electronic component socket or mounting element configuration (e.g., TR4(U)), and the third set of retention holes 302C can be arranged to align with mounting elements of a substrate with a third electronic component socket or mounting element configuration (e.g., AM4/5).

Although each set of retention holes 302A, 302B, and 302C of the bracket 300 shown in FIG. 3 includes two retention holes (resulting in six total retention holes 302), a set of retention holes of a bracket of a modular retainer can include any quantity of retention holes in accordance with the disclosed subject matter (e.g., each set of retention holes can include a single retention hole, resulting in three total retention holes for the bracket; or each set of retention holes can include three retention holes, resulting in nine total retention holes for the bracket; or each set of retention holes can include four retention holes, resulting in twelve total retention holes for the bracket, etc.). Furthermore, although the bracket 300 shown in FIG. 3 includes three sets of retention holes 302A, 302B, and 302C, a bracket of a modular retainer can include any quantity of sets of retention holes associated with different mounting element configurations. Still furthermore, although the retention holes 302 of the bracket 300 shown in FIG. 3 are illustrated as through holes, the retention holes 302 may include threads in some embodiments.

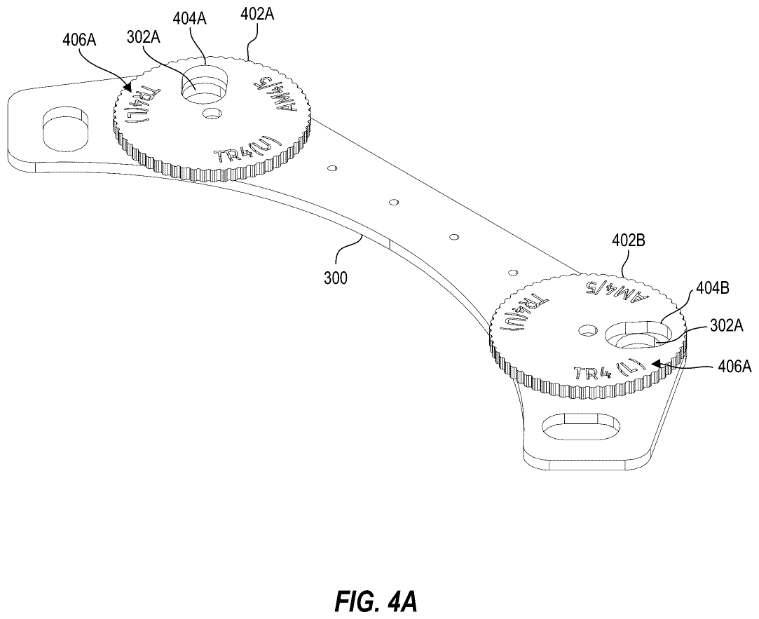

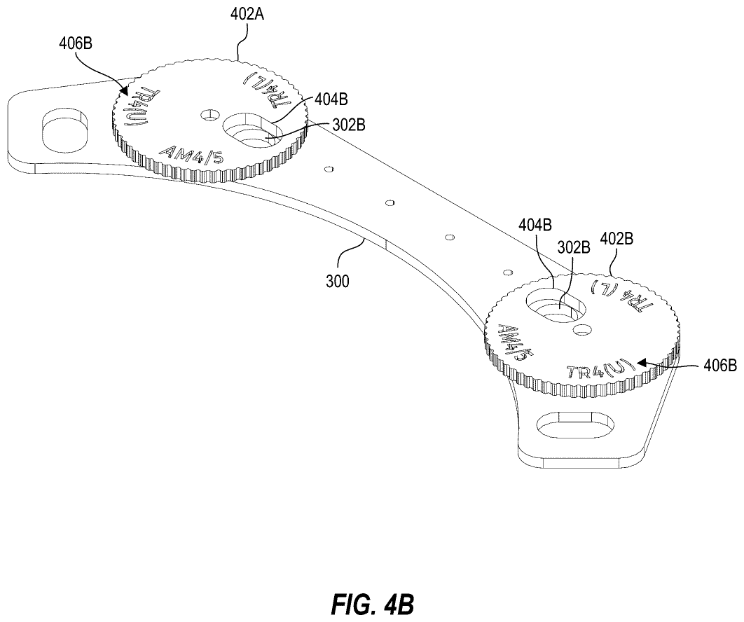

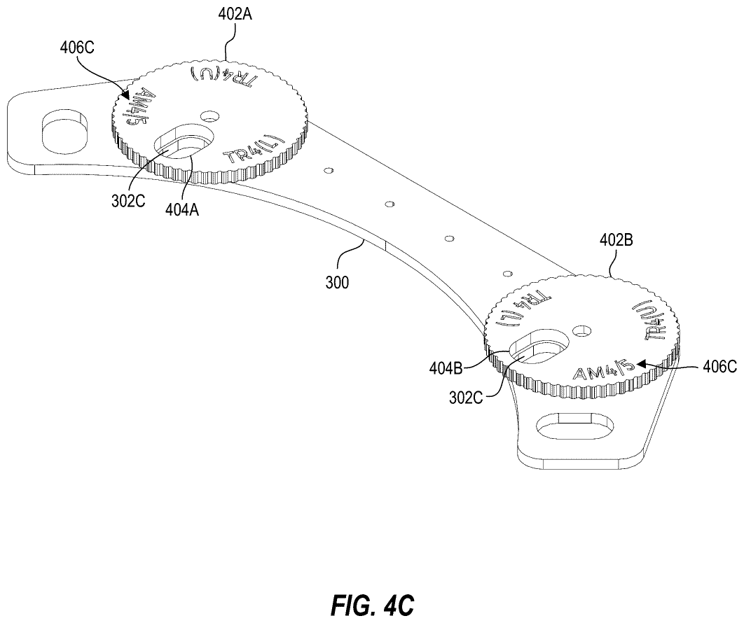

FIGS. 4A, 4B, and 4C illustrate isometric views of the bracket 300 shown in FIG. 3 with movable selectors 402A and 402B positioned proximate to the bracket 300. The movable selectors 402A and 402B shown in FIGS. 4A, 4B, and 4C include indexable features 404A and 404B, respectively. The movable selectors 402A and 402B can be indexed/moved to various predefined positions to facilitate alignment of the indexable features 404A and 404B with a selected set of retention holes 302A, 302B, or 302C of the bracket 300. For example, FIG. 4A illustrates the movable selectors 402A and 402B arranged in a first position, in which the indexable features 404A and 404B of the movable selectors 402A and 402B are aligned with the first set of retention holes 302A of the bracket 300. FIG. 4B illustrates the movable selectors 402A and 402B arranged in a second position, in which the indexable features 404A and 404B of the movable selectors 402A and 402B are aligned with the second set of retention holes 302B of the bracket 300. FIG. 4C illustrates the movable selectors 402A and 402B arranged in a third position, in which the indexable features 404A and 404B of the movable selectors 402A and 402B are aligned with the third set of retention holes 302C of the bracket 300.

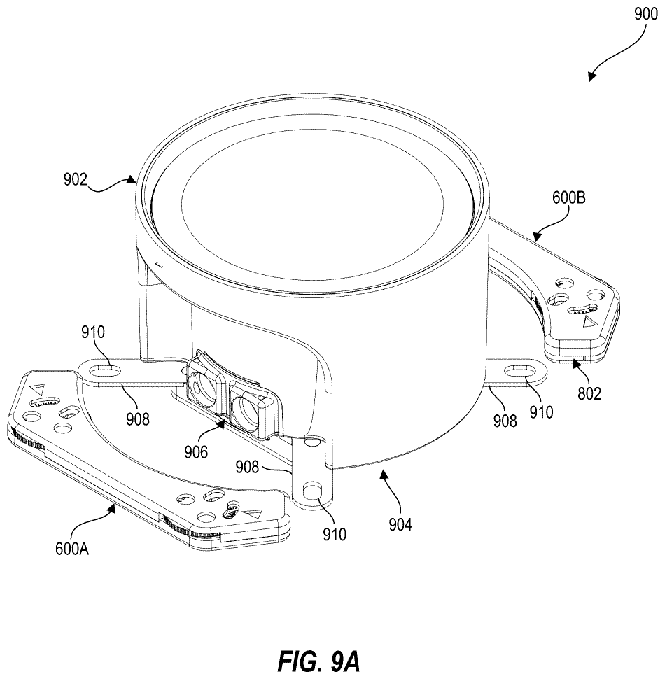

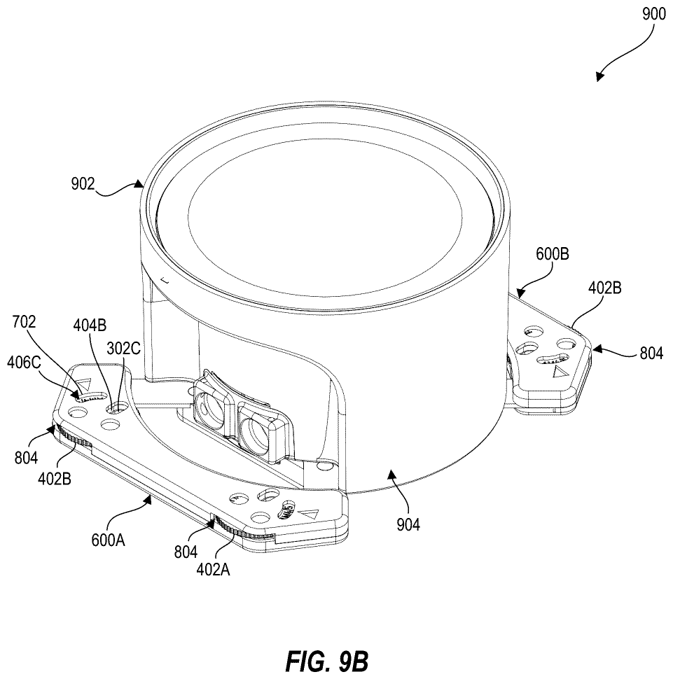

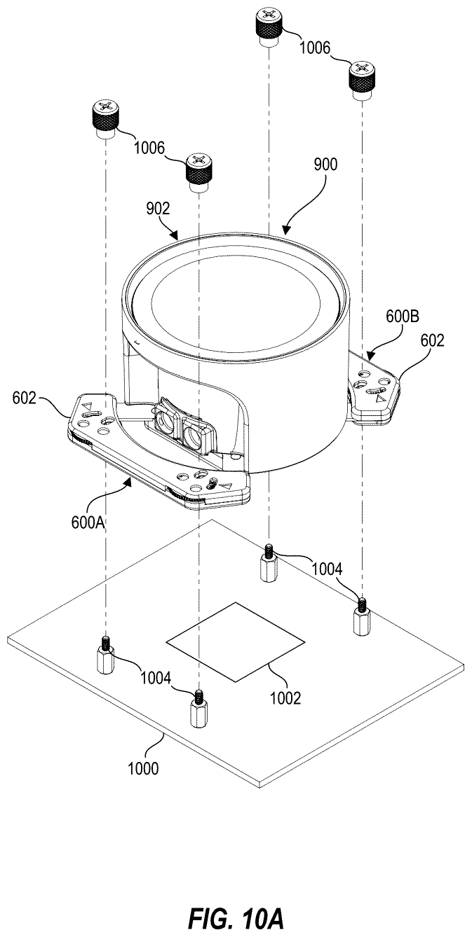

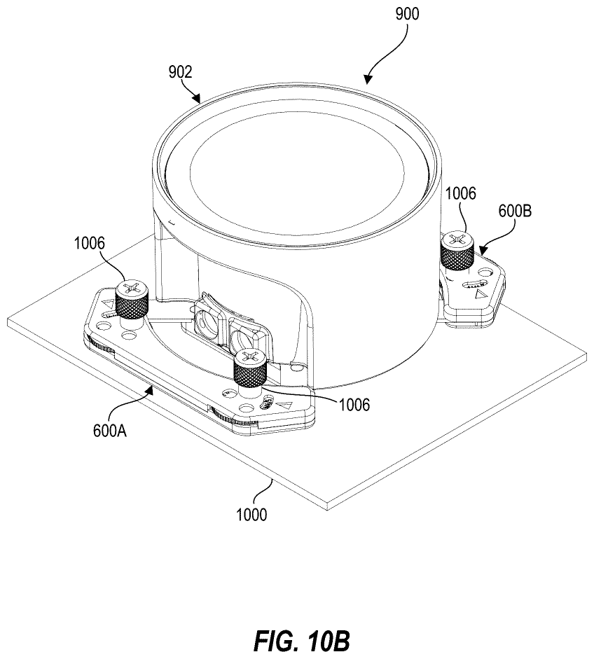

When the indexable features 404A and 404B of the movable selectors 402A and 402B are positioned as shown in FIG. 4A, the movable selectors 402A and 402B obscure the second set of retention holes 302B and the third set of retention holes 302C. Similarly, when the indexable features 404A and 404B of the movable selectors 402A and 402B are positioned as shown in FIG. 4B, the movable selectors 402A and 402B obscure the first set of retention holes 302A and the third set of retention holes 302C. Furthermore, when the indexable features 404A and 404B of the movable selectors 402A and 402B are positioned as shown in FIG. 4C, the movable selectors 402A and 402B obscure the first set of retention holes 302A and the second set of retention holes 302B. In this regard, the movable selectors 402A and 402B can be configured to selectively reveal one set of retention holes 302 of the bracket 300 at a time, which can mitigate user error in utilizing a modular retainer to mount a heat transfer unit to a substrate (see FIGS. 9A-10B).

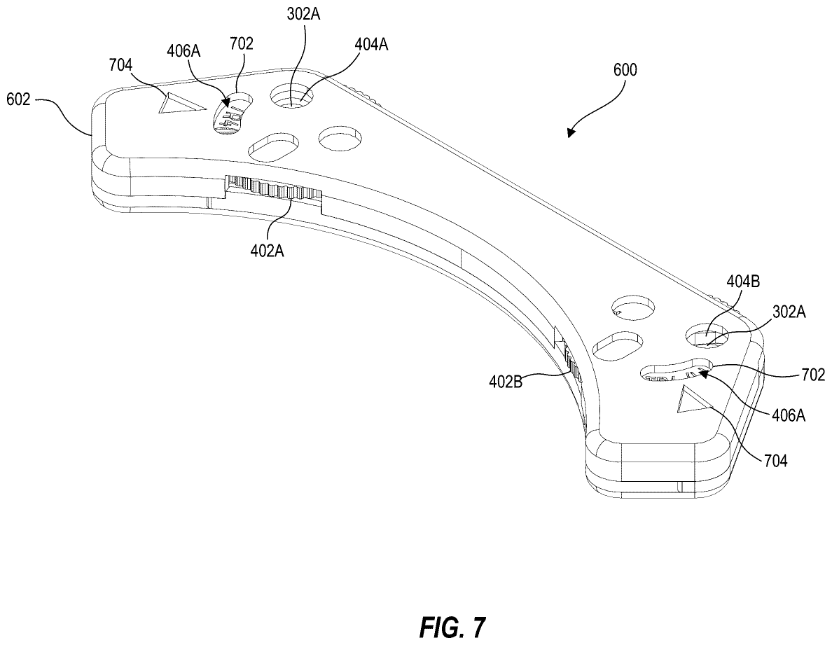

In the example shown in FIGS. 4A, 4B, and 4C, the indexable features 404A and 404B of the movable selectors 402A and 402B include location indicators 406A, 406B, and 406C. Location indicator 406A is associated with the first position (e.g., alignment of the indexable features 404A and 404B of the movable selectors 402A and 402B with the first set of retention holes 302A, as shown in FIG. 4A), location indicator 406B is associated with the second position (e.g., alignment of the indexable features 404A and 404B of the movable selectors 402A and 402B with the second set of retention holes 302B, as shown in FIG. 4B), and location indicator 406C is associated with the third position (e.g., alignment of the indexable features 404A and 404B of the movable selectors 402A and 402B with the third set of retention holes 302C, as shown in FIG. 4C). As will be described in more detail hereinafter with reference to FIG. 7, the location indicators 406A, 406B, and 406C can be selectively revealed (e.g., via a viewing window of a housing of a modular retainer) to assist users in selecting and/or achieving a desired positioning of a movable selector 402A or 402B relative to a bracket 300 of a modular retainer.

In the example shown in FIGS. 4A, 4B, and 4C, the movable selectors 402A and 402B are implemented as rotatable discs that are selectively rotatable into the various positions shown in FIGS. 4A, 4B, and 4C. The indexable features 404A and 404B shown in FIGS. 4A, 4B, and 4C are implemented as modular mounting holes within the rotatable discs (e.g., holes for which positioning is modifiable to accommodate different configurations of mounting features/elements). In some implementations, the movable selectors 402A and 402B and/or the bracket 300 may include one or more positioning features (e.g., locks, stops, detents, bosses, etc.) configured to define the aligned positions of the movable selectors 402A and 402B (e.g., the positions shown in FIGS. 4A, 4B, and 4C) or to control or limit movement of the movable selectors 402A and 402B when an aligned position has been reached. In some implementations, the aligned positions of the movable selectors 402A and 402B are defined by alignment of the indexable features 404A and 404B with a set of retention holes 302A, 302B, or 302C of the bracket 300.

Although the movable selectors 402A and 402B shown in FIGS. 4A, 4B, and 4C are implemented as rotatable discs, other configurations are within the scope of the present disclosure (e.g., translatable or slidable plates). Furthermore, although FIGS. 4A, 4B, and 4C illustrate two movable selectors 402A and 402B utilized in conjunction with a bracket 300, any quantity of movable selectors (e.g., more than two) may be utilized in conjunction with a bracket of a modular retainer. Still furthermore, although the movable selectors 402A and 402B shown in FIGS. 4A, 4B, and 4C each include a single indexable feature 404A and 404B implemented as a modular mounting hole, a movable selector can include any quantity of indexable features, and the indexable features can take on additional or alternative forms (e.g., studs, protrusions, recesses, etc.).

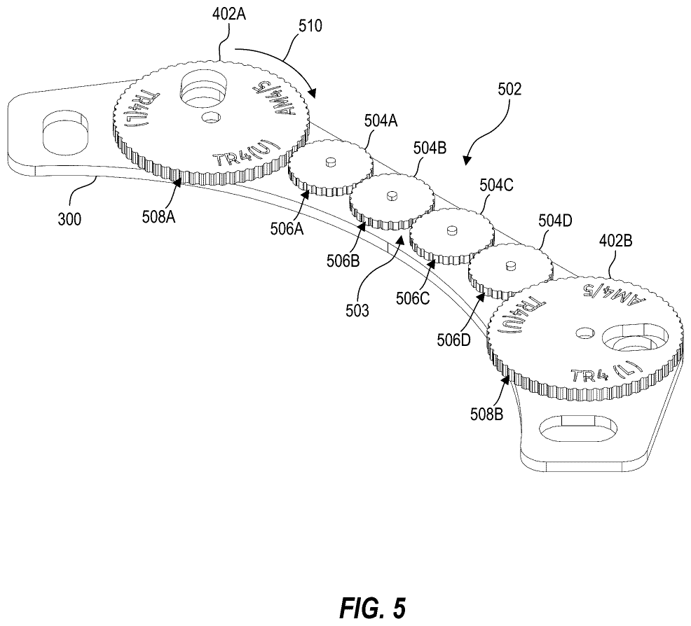

FIG. 5 illustrates an isometric view of the bracket 300 and movable selectors 402A and 402B shown in FIGS. 4A, 4B, and 4C with a coupling element 502 (or coupler) configured to couple the movable selectors 402A and 402B with each other. As shown in FIG. 5, the coupling element 502 is implemented as a gear train 503. The illustrated gear train 503 includes a plurality of gears 504A, 504B, 504C, and 504D that mesh with each other. Further, the outermost gears 504A and 504D respectively mesh with the movable selectors 402A, 402B. For example, the outermost gear 504A defines a plurality of cogs 506A that mesh with complementarily configured cogs 508A defined by the movable selector 402A. Similarly, the outermost gear 504D defines a plurality of cogs 506D that mesh with complementarily configured cogs 508B defined by the movable selector 402B. The cogs of outermost gear 504A also mesh with cogs 506B defined by an adjacent internal gear 504B, which in turn mesh with the cogs 506C defined by another adjacent internal gear 504C. The cogs 506C defined by internal gear 504C mesh with the cogs 508B defined by the movable selector 402B.

Under the configuration shown in FIG. 5, urging one of the movable selectors 402A or 402B to rotate urges each of the gears 504A, 504B, 504C, and 504D of the gear train 503 and the other of the movable selectors 402A or 402B to rotate as well. For instance, urging movable selector 402A to rotate in a first rotational direction 510 urges gear 504A to rotate in a second rotational direction (opposite the first rotational direction 510), which urges gear 504B to rotate in the first rotational direction 510, which urges gear 504C to rotate in the second rotational direction, which urges gear 504D to rotate in the first rotational direction 510, which urges movable selector 402B to rotate in the second rotational direction. Similarly, urging movable selector 402A to rotate in the second rotational direction urges gear 504A to rotate in the first rotational direction 510, which urges gear 504B to rotate in the second rotational direction, which urges gear 504C to rotate in the first rotational direction 510, which urges gear 504D to rotate in the second rotational direction, which urges movable selector 402B to rotate in the first rotational direction 510. Also, urging movable selector 402B to rotate in the first rotational direction 510 urges gear 504D to rotate in the second rotational direction, which urges gear 504C to rotate in the first rotational direction 510, which urges gear 504B to rotate in the second rotational direction, which urges gear 504A to rotate in the first rotational direction 510, which urges movable selector 402A to rotate in the second rotational direction. Furthermore, urging movable selector 402B to rotate in the second rotational direction urges gear 504D to rotate in the first rotational direction 510, which urges gear 504C to rotate in the second rotational direction, which urges gear 504B to rotate in the first rotational direction 510, which urges gear 504A to rotate in the second rotational direction, which urges movable selector 402A to rotate in the first rotational direction 510. In this regard, the coupling element 502 can transfer motion of one movable selector 402A to the other movable selector 402B, which can enable the movable selectors 402A and 402B to rotate simultaneously (e.g., in opposite directions). The coupling element 502 can thus facilitate coupling between the movable selectors 402A and 402B such that movement of one of the movable selectors 402A or 402B to the first position (or the second position or the third position) causes movement of the other movable selector 402A or 402B to the first position (or the second position or the third position).

Although FIG. 5 illustrates an embodiment in which the coupling element 502 is implemented as a gear train 503 with four gears 504A, 504B, 504C, and 504D intervening between the movable selectors 402A and 402B, a coupling element 502 implemented as a gear train 503 can include any quantity of gears. Also, although the gear train 503 shown in FIG. 5 is based on spur gears, other forms may be utilized, such as helical gears, rack-and-pinion gears, bevel gears, miter gears, worm gears, etc. Furthermore, a coupling element 502 can implement additional or alternative types of coupling mechanisms to couple the movable selectors 402A and 402B with one another, such as belts, pulleys, chain/sprockets, friction wheels, combinations thereof, and/or others. In some implementations, the cogs 508A and 508B defined by the movable selectors 402A and 402B, respectively, directly mesh with one another to facilitate transferring of motion of one movable selector to the other (the cogs 508A and 508B may thus be regarded, in some instances, as a coupling element or coupler). Additionally, as noted above with reference to FIGS. 4A, 4B, and 4C, a modular retainer can include more than two movable selectors. Correspondingly, a modular retainer can include multiple coupling elements (using the same or different coupling element modalities) to enable urging of one movable selector to cause urging of the other movable selectors.

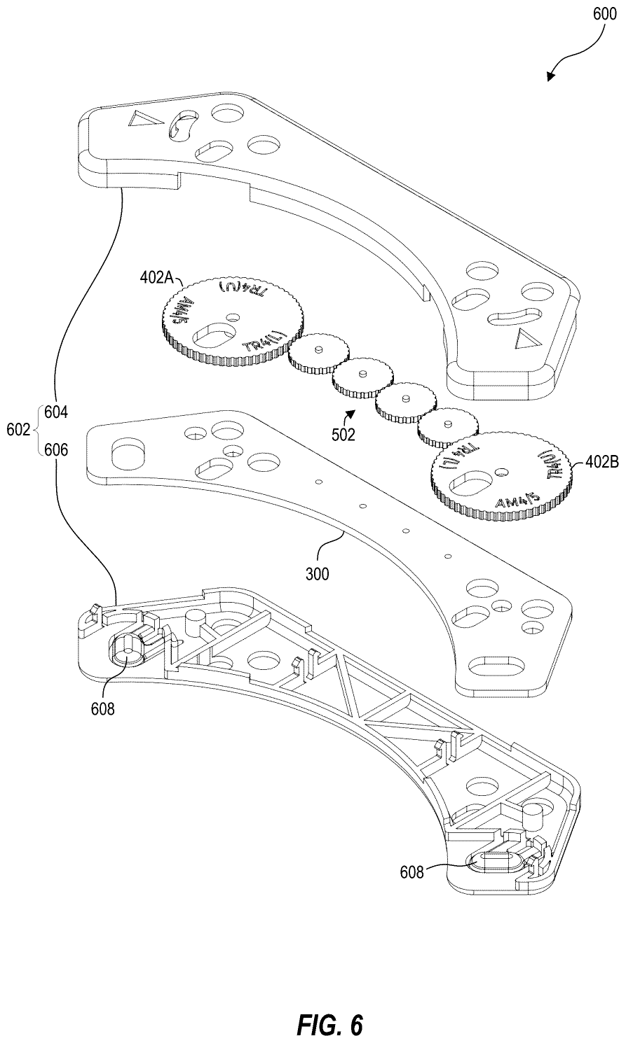

FIG. 6 illustrates an exploded view of a modular retainer 600 that includes the bracket 300, movable selectors 402A and 402B, and a coupling element 502 as described hereinabove. The modular retainer 600 shown in FIG. 6 includes a housing 602 composed of a cover 604 and a base 606. When assembled, the cover 604 and the base 606 can operate as a clamshell enclosure that at least partially encloses/covers the bracket 300, the movable selectors 402A and 402B, and the coupling element 502. In some implementations, the housing 602 movably secures (e.g., rotatably or movable retains) the movable selectors 402A and 402B and/or the coupling element 502 to the bracket 300 (e.g., via shafts, bosses, hubs, bores, couplings, and/or receptacles positioned on the cover 604, the base 606, the movable selectors 402A and 402B, the coupling element 502, and/or the bracket 300). The housing 602 can additionally provide a measure of electrical insulation for the bracket 300 and/or other metallic components of the modular retainer 600.

FIG. 7 illustrates an isometric view of the modular retainer 600 shown in FIG. 6 in assembled form. As noted above with reference to FIGS. 4A, 4B, and 4C, the movable selectors 402A and 402B may include location indicators 406A, 406B, and 406C associated with different positions of the movable selectors 402A and 402B. In the example shown in FIG. 7, the housing 602 includes viewing windows 702 that can align with and reveal the location indicators 406A, 406B, or 406C indicating the current positional alignment of the movable selectors 402A and 402B. For instance, in FIG. 7, the viewing windows 702 reveal location indicators 406A of the movable selectors 402A and 402B, indicating that the movable selectors 402A and 402B are in the first position (e.g., with the indexable features 404A and 404B of the movable selectors 402A and 402B aligned with the first set of retention holes 302A of the bracket 300, for TR4(L)). The viewing windows 702 and the location indicators 406A, 406B, and 406C can enable users to readily ascertain the current positioning of the movable selectors 402A and 402B and can assist users in achieving a desired positioning (e.g., for a particular socket or mounting element configuration). As shown in FIG. 7, the housing 602 can further include selector arrows 704 to emphasize to users the location indicator of the current alignment of the movable selectors 402A and 402B.

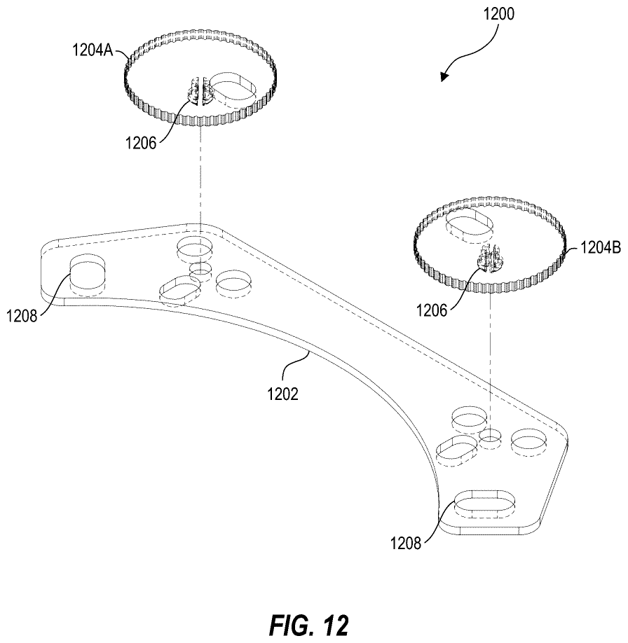

Although the modular retainer 600 includes three location indicators 406A, 406B, and 406C on each movable selector 402A and 402B, a movable selector of a modular retainer can include any number of location indicators (e.g., two location indicators, four or more location indicators, which may each correspond to a respective positional configuration of alignment with a respective set of retention holes of a bracket) or no location indicators (see FIG. 12). Different movable selectors of the same modular retainer can have different quantities of movable selectors (e.g., one movable selector can have two or more location indicators, while the other movable selector can have no location indicators). Furthermore, although the modular retainer 600 is illustrated as including two viewing windows (one associated with each movable selector 402A, 402B), a modular retainer can include any quantity of viewing windows (e.g., a housing may include a viewing window for one or more movable selectors but not for one or more other movable selectors) or no viewing windows (e.g., a housing may omit viewing windows, or a modular retainer can omit a housing: see FIG. 12).

Referring to FIG. 6, the modular retainer 600 can include one or more latching features 608 (or catches) that are configured to engage with corresponding latching features of a heat transfer unit. In the example shown in FIG. 6, the latching features 608 are implemented as detents or protrusions on the housing 602, which are configured to engage with one or more surfaces of the heat transfer unit that define recesses or openings (an opposite configuration may be used, with the detents or protrusions defined by the heat transfer unit rather than by the housing 602). The latching feature(s) 608 of a modular retainer 600 can take on additional or alternative forms within the scope of the present disclosure (e.g., to accommodate screw/bolt fastening, snap-fit joints, adhesives/welding, interference fits, dovetail joints, pins, clamps, and/or others). Furthermore, in some instances, a modular retainer can include additional or alternative latching features on other components thereof (e.g., on the bracket 300, see FIG. 12 where the latching features of the modular retainer comprise surfaces defining holes on the bracket).

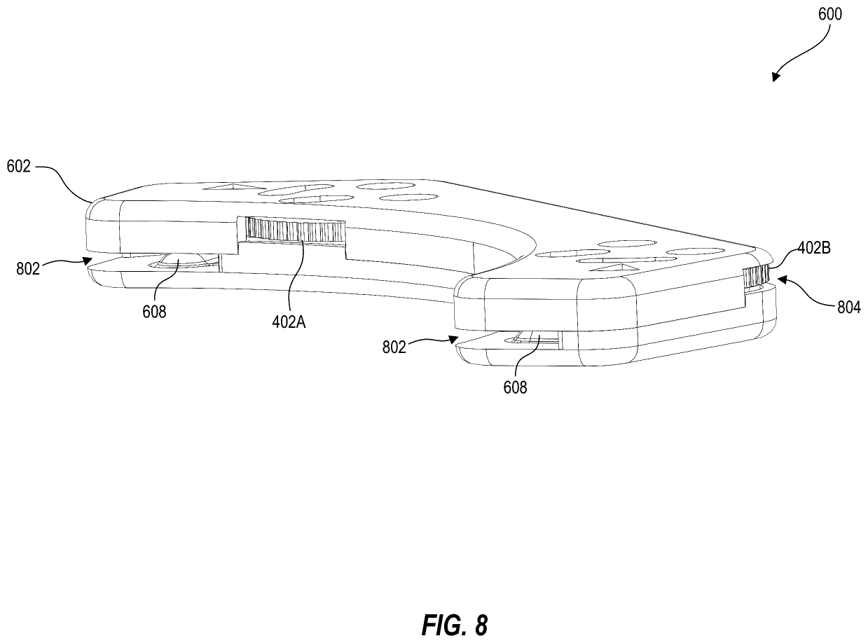

FIG. 8 illustrates a front perspective view of the modular retainer 600 in assembled form, showing the latching features 608 thereof. As shown in FIG. 8, the housing 602 of the modular retainer 600 forms slots 802 when assembled, and the latching features 608 are positioned within the slots 802. The slots 802 may thus receive the corresponding latching features of a heat transfer unit as they advance into engagement with the latching features 608 of the modular retainer 600, which can contribute to the coupling or joint strength between the modular retainer 600 and the heat transfer unit.

FIG. 8 furthermore illustrates that the housing 602 of the modular retainer 600 may form an access opening 804 through which at least part of the movable selectors 402A and 402B may extend (e.g., protruding outward from the housing 602). Segments of the movable selectors 402A and 402B can thus be exposed externally (relative to an external surface defined by the housing 602), permitting the movable selectors 402A and 402B to be accessed by users to enable users to modify the positioning of the movable selectors 402A and 402B to achieve a desired positional configuration for alignment with mounting elements of a substrate. For instance, a user may urge a movable selector 402A or 402B in rotation, thereby urging the gear train 503 to transfer corresponding motion to the other of the movable selectors 402A or 402B (or to multiple other movable selectors, in implementations where the modular retainer includes more than two movable selectors and multiple coupling elements to transfer motion from one movable selector to the remaining movable selectors).

FIG. 9A illustrates an isometric view of a heat transfer system 900 including modular retainers 600A and 600B and a heat transfer unit 902. Although the heat transfer system 900 shown in FIG. 9A includes two modular retainers 600A and 600B, a heat transfer system can include any quantity of modular retainers in conjunction with a heat transfer unit (e.g., one or more than two modular retainers).

FIG. 9A illustrates the modular retainers 600A and 600B positioned about the heat transfer unit 902. In the example shown in FIG. 9A, the modular retainers 600A and 600B correspond to and include components/features of the modular retainer 600 described hereinabove. The heat transfer unit 902 includes a heat sink 904 (on the underside) and fluid ports 906 for receiving coolant lines to facilitate heat transfer for an electronic component (or other heat source) in contact with the heat sink 904. As noted above, other types of heat transfer units may be utilized in conjunction with one or more modular retainers as described herein. The heat transfer unit 902 also includes one or more brackets 908 that define latching features 910 (implemented as holes or recesses). The bracket(s) 908 is/are configured to insert into the slots 802 to enable the surfaces defining the bracket(s) 908 to engage with the latching features 608 (e.g., implemented as detents) of the modular retainers 600A and 600B. Similar to the latching features 608 of the modular retainers 600A and 600B, the latching features 910 of the heat transfer unit 902 can take on various forms.

FIG. 9B illustrates an isometric view of the heat transfer system 900 shown in FIG. 9A with the modular retainers 600A and 600B engaged with the heat transfer unit 902 via the latching features 910 of the heat transfer unit 902 and the latching features 608 of the modular retainers 600A and 600B. Under the configuration shown in FIG. 9B, the movable selectors 402A and 402B of the modular retainers 600A and 600B may remain accessible to users via the access openings 804. A user may thus adjust the movable selectors 402A and 402B of the modular retainers 600A and 600B to a desired position to align with mounting elements of a substrate on which the heat transfer system 900 is intended for installation. In the example shown in FIG. 9B, the movable selectors 402A and 402B of the modular retainers 600A and 600B are positioned to align with AM4/5 mounting elements (e.g., the “third position” described hereinabove, where the indexable features 404A and 404B are aligned with the third set of retention holes 302C and where the location indicators 406C are visible through the viewing windows 702).

FIG. 10A illustrates an isometric view of an electronic device including the heat transfer system 900 shown in FIG. 9B positioned over an electronic component 1002 mounted to a substrate 1000. In the example shown in FIG. 10A, the substrate 1000 includes mounting elements 1004 implemented as threaded bolts configured to threadedly engage with corresponding mounting elements 1006 implemented as mounting nuts. Other types of mounting elements 1004 and/or corresponding mounting elements 1006 are possible, such as where the mounting elements 1004 comprise mounting nuts fixed to the substrate 1000 and where the corresponding mounting elements 1006 comprise threaded bolts, or where additional or alternative mounting features are utilized (e.g., pins, rods, rivets, screws, substrate holes, studs, wire, and/or others).

The mounting elements 1004 are positioned on the substrate 1000 relative to the mounted position of the electronic component 1002 according to a predefined socket configuration (e.g., TR4(L), TR4(U), AM4/5, and/or others). In the example shown in FIG. 10A, the mounting elements 1004 are arranged on the substrate 1000 about the electronic component 1002 in accordance with the AM4/5 configuration. As noted above, the modular retainers 600A and 600B are adjusted to align with the AM4/5 mounting elements, permitting the mounting elements 1004 to align with the modular retainers 600A and 600B (e.g., extending through the brackets 300, indexable features 404A and 404B, and corresponding holes in the housings 602 of the modular retainers 600A and 600B) when the heat transfer system 900 is advanced toward the substrate 1000.

FIG. 10B illustrates an isometric view of the electronic device shown in FIG. 10A with the heat transfer system 900 mounted to the substrate 1000 via engagement of the corresponding mounting elements 1006 with the mounting elements 1004. The corresponding mounting elements 1006 may exert downward mounting force on the modular retainers 600A and 600B (e.g., on the brackets 300 thereof), which may transfer the mounting force to the heat transfer unit 902 to bring the heat transfer unit 902 into contact with the electronic component 1002. The heat transfer unit 902 may thus be mounted to the substrate 1000 via the modular retainers 600A and 600B in a manner that maintains thermal contact between the heat transfer unit 902 (e.g., the heat sink 904) and the electronic component 1002.

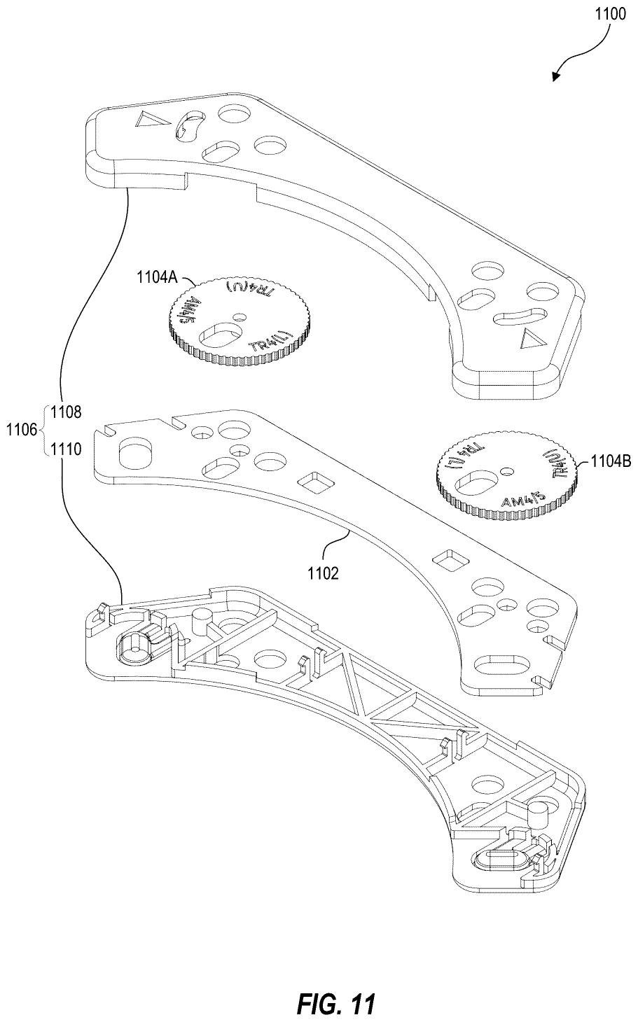

FIGS. 11 and 12 illustrate isometric views of alternative embodiments of modular retainers. For instance, FIG. 11 illustrates an embodiment of a modular retainer 1100 that includes a bracket 1102, movable selectors 1104A and 1104B, and a housing 1106 composed of a cover 1108 and a base 1110. The modular retainer 1100 omits a coupling element between movable selectors 1104A and 1104B thereof.

FIG. 12 illustrates an embodiment of a modular retainer 1200 that includes a bracket 1202 and movable selectors 1204A and 1204B. The modular retainer 1200 omits a housing and omits a coupling element between the movable selectors 1204A and 1204B thereof. In the example shown in FIG. 12, the movable selectors 1204A and 1204B include snap fit mounting features 1206 (e.g., on the underside of the movable selectors 1204A and 1204B, shown in hidden lines) that enable the movable selectors 1204A and 1204B to pivotally connect directly to the bracket 1202. Other connection features that permit pivotal connection between the movable selectors 1204A and 1204B and the bracket 1202 may be utilized, such as pivot pins, joints, bearings, etc. Furthermore, the bracket 1202 of the modular retainer 1200 includes surfaces defining latching features 1208 (implemented as holes), which enable the bracket 1202 to connect to heat transfer units. For example, to connect to the heat transfer unit 902, the latching features 1208 of the bracket 1202 of the modular retainer 1200 may be aligned with the latching features 910 of the bracket(s) 908 of the heat transfer unit 902, and one or more connection elements such as bolts/nuts or others may interact with the surfaces defining the latching features 1208 and 910 to connect the modular retainer 1200 to the heat transfer unit 902.

### V. Other Embodiments

The embodiments of disclosed principles described above generally concern mechanical retention systems, devices, components, and related methods.

Nonetheless, the previous description is provided to enable a person skilled in the art to make or use the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by reference in its entirety for all purposes.

Those of ordinary skill in the art will appreciate that the exemplary embodiments disclosed herein can be adapted to various configurations and/or uses without departing from the disclosed principles. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of mechanical retention components, devices, and related systems and methods that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

The appended claims are not intended to be limited to the embodiments shown herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

We claim:

1. A retainer, comprising:
a bracket configured to engage with a heat transfer unit, the bracket defining a plurality of retention holes; and
a movable selector comprising one or more indexable features that selectively align with a first one or more of the plurality of retention holes defined by the bracket when the movable selector is in a first position and with a second one or more of the plurality of retention holes defined by the bracket when the movable selector is in a second position.

2. The retainer according to claim 1, wherein the movable selector selectively obscures a portion of the second one or more of the plurality of retention holes defined by the bracket when the movable selector is in the first position.

3. The retainer according to claim 2, wherein the movable selector selectively obscures a portion of the first one or more of the plurality of retention holes defined by the bracket when the movable selector is in the second position.

4. The retainer according to claim 1, wherein the one or more indexable features comprises one or more modular mounting holes.

5. The retainer according to claim 1, wherein the movable selector comprises a rotatable disc that is selectively rotatable from the first position to the second position and from the second position to the first position.

6. The retainer according to claim 1, further comprising a housing that at least partially covers the bracket and the movable selector, wherein the housing movably secures the movable selector to the bracket.

7. The retainer according to claim 6, wherein the movable selector comprises:
a first location indicator associated with the first position; and
a second location indicator associated with the second position.

8. The retainer according to claim 7, wherein the housing comprises a viewing window, wherein the first location indicator of the movable selector aligns with the viewing window when the movable selector is in the first position, and wherein the second location indicator of the movable selector aligns with the viewing window when the movable selector is in the second position.

9. The retainer according to claim 6, wherein the housing or the bracket defines a catch, and wherein the bracket is configured to engage with the heat transfer unit via the catch of the housing or the bracket cooperatively engaging with a corresponding feature of the heat transfer unit to retain the retainer in a selected position relative to the heat transfer unit.

10. The retainer according to claim 9, wherein the housing comprises the catch, wherein the catch comprises a detent, and wherein the corresponding feature of the heat transfer unit comprises one or more surfaces of the heat transfer unit that define a recess.

11. The retainer according to claim 9, wherein the housing defines a slot configured to receive the corresponding feature of the heat transfer unit, and wherein the catch defined by the housing or the bracket is positioned within the slot.

12. The retainer according to claim 6, wherein the plurality of retention holes defined by the bracket is a first plurality of retention holes, wherein the bracket further defines a second plurality of retention holes.

13. The retainer according to claim 12, wherein the movable selector comprises a first movable selector, wherein the retainer further comprises a second movable selector, the second movable selector comprising one or more second indexable features, wherein the one or more second indexable features selectively align with a first one or more of the second plurality of retention holes defined by the bracket when the second movable selector is in a corresponding first position and with a second one or more of the second plurality of retention holes defined by the bracket when the second movable selector is in a corresponding second position.

14. The retainer according to claim 13, wherein the housing at least partially covers the second movable selector and movably secures the second movable selector to the bracket.

15. The retainer according to claim 14, further comprising a coupler that couples the movable selector to the second movable selector such that:
movement of the movable selector to the first position causes movement of the second movable selector to the corresponding first position,
movement of the movable selector to the second position causes movement of the second movable selector to the corresponding second position,
movement of the second movable selector to the corresponding first position causes movement of the movable selector to the first position, and
movement of the second movable selector to the corresponding second position causes movement of the movable selector to the second position.

16. The retainer according to claim 15, wherein the coupler comprises a gear train, wherein the movable selector and the second movable selector each comprise cogs, and wherein the gear train comprises one or more gears engaged with the cogs of the movable selector and the second movable selector.

17. The retainer according to claim 15, wherein the housing at least partially covers the coupler or movably secures the coupler to the bracket.

18. A heat transfer system, comprising:
a heat transfer unit; and
a retainer, comprising:
a latching feature configured to engage with a corresponding latching feature of the heat transfer unit;
a bracket defining a plurality of retention holes; and
a movable selector comprising one or more indexable features that selectively align with a first one or more of the plurality of retention holes defined by the bracket when the movable selector is in a first position and with a second one or more of the plurality of retention holes defined by the bracket when the movable selector is in a second position.

19. The heat transfer system according to claim 18, wherein the retainer further comprises a housing that at least partially covers the movable selector and that movably secures the movable selector to the bracket, wherein the housing forms a slot configured to receive the corresponding latching feature of the heat transfer unit, and wherein the latching feature of the retainer is positioned within the slot.

20. The heat transfer system according to claim 18, wherein the one or more indexable features of the movable selector selectively align with a third one or more of the plurality of retention holes defined by the bracket when the movable selector is in a third position.

21. The heat transfer system according to claim 18, further comprising a second retainer, the second retainer comprising:
a second latching feature configured to engage with a second corresponding latching feature of the heat transfer unit;
a second bracket defining a second plurality of retention holes; and
a second movable selector comprising one or more second indexable features that selectively align with a first one or more of the second plurality of retention holes defined by the second bracket when the second movable selector is in a corresponding first position and with a second one or more of the second plurality of retention holes defined by the second bracket when the second movable selector is in a corresponding second position.

22. An electronic device, comprising:
a substrate;
a heat transfer unit;
an electronic component mounted to the substrate, the substrate comprising one or more mounting elements configured to allow a user to mount the heat transfer unit to the substrate while maintaining thermal contact between the heat transfer unit and the electronic component, each of the one or more mounting elements being positioned relative to a mounted position of the electronic component; and
a retainer having a bracket defining a plurality of retention holes and a movable selector having one or more indexable features that selectively align with a first one or more of the plurality of retention holes defined by the bracket when the movable selector is in a first position and with a second one or more of the plurality of retention holes defined by the bracket when the movable selector is in a second position, wherein selected ones of the plurality of retention holes defined by the bracket and selected ones of the one or more indexable features of the movable selector align with each of the one or more mounting elements defined by the substrate when the movable selector is in a selected position.
